(19) United States
(12) Patent Application Publication
(10) Pub. No.: US 2012/0127659 A1
(43) Pub. Date: May 24, 2012

(54) HEATING SPREADING ELEMENT WITH ALN FILM AND METHOD FOR MANUFACTURING THE SAME

(76) Inventors: SunZen CHEN, Hsinchu (TW); Puru Lin, Hsinchu (TW); Henry J. H. Chen, Hsinchu (TW)

(21) Appl. No.: 13/196,218

(22) Filed: Aug. 2, 2011

(30) Foreign Application Priority Data
Nov. 24, 2010 (TW) 099140602

(51) Int. Cl. H05K 7/20; B21D 53/02; F28F 7/00

(52) U.S. Cl. 361/688; 165/185; 29/890.03

(57) ABSTRACT

The present invention relates to a heat spreading element with an AlN film including: a substrate which may be composed of a single bulk material, a multi-layered sample, or a composite material; and an AlN film deposited on the surface of the substrate, wherein the thickness of the AlN film is in a range of 1 nm to 10 μm, and the AlN film is used to conduct the heat from a heat-generating device to the substrate, and method for manufacturing the same.

### BACKGROUND OF THE INVENTION

1. Field of the Invention

The present invention relates to a heat-spreading element with an AlN film and a method for manufacturing the same and, more particularly, to a heat-spreading element with an AlN film manufactured by a coating process and a method for manufacturing the same.

2. Description of Related Art

As the electronic industry progresses, various high-power components have be applied more and more widely. For these high-power components, the high performances on heat conducting and dissipating are crucially demanded. Or, the life-time of the electronics or semiconductor devices may be shortened undesirably.

AlN is a good material for heat dissipation. In general, AlN heat dissipaters are AlN bulks manufactured by sintering. However, AlN bulks require to be manufactured by sintering at 1400-1900° C. Since too many parameters may affect the sintering properties, it is not easy to obtain a well-sintered AlN and it is easy to observe run-to-run difference. In addition, if the sintering process is not under well-controlled, the sintered AlN bulks may have too many voids, resulting in poor mechanical and thermal-conduction properties thereof. If the AlN bulks with poor properties are used, the products may result in low reliability. Besides, applying the sintered AlN bulk as a heat-spreading element may consume more materials owing to larger volume of the bulk.

Hence, there is an urgent need to develop a heat-spreading element of AlN and a method for manufacturing the same so as to solve the problem about easy occurrence of run-to-run difference in the sintered AlN bulks and thus to improve the reliability of the products and to reduce the difficulty and cost of the process.

### SUMMARY OF THE INVENTION

The object of the present invention is to provide a heat-spreading element with an AlN film for being integrated with current semiconductor processes.

Another object of the present invention is to provide a method for manufacturing a heat-spreading element with an AlN film so as to produce heat-spreading elements without run-to-run difference.

To achieve the object, the heat-spreading element with an AlN film in the present invention includes: a substrate having an upper surface and a lower surface; and an AlN film deposited on the upper surface of the substrate, wherein the AlN film has a thickness from 1 nm to 10 μm and serves as a medium for heat conduction.

In addition, the method for manufacturing a heat-spreading element with an AlN film in the present invention includes the following steps: (A) providing a substrate having an upper surface and a lower surface; and (B) forming an AlN film deposited on the upper surface of the substrate, wherein the AlN film has a thickness from 1 nm to 10 μm and serves as a medium for heat conduction.

Because sintering is not adopted in the method for manufacturing the heat-spreading element with an AlN film in the present invention, the problem about AlN bulks having run-to-run difference owing to difficult control of the sintering process can be solved. Furthermore, the heat-spreading element with an AlN film and its manufacturing method in the present invention can be integrated with common semiconductor processes and thus be applied in various electronic devices.

Since an AlN film in the heat-spreading element and its manufacturing method is formed by deposition in the present invention, the material, shape, and structure of the substrate are not limited particularly. In the heat-spreading element with an AlN film and its manufacturing method of the present invention, the substrate can be a rigid substrate or a flexible substrate. For example, the substrate can be a Si substrate, a metal substrate, a glass substrate, a plastic substrate, a ceramic substrate, a Si substrate coated with a metal film, a C—C composite substrate, a C—C composite substrate coated with a metal film, or a substrate with multiple films. Furthermore, the substrate can be a semiconductor chip or a package substrate with circuits. Among them, the metal substrate or film can be made of Cu, Au, Pt, W, Ti, Al, Ag, Ni, or an alloy thereof. The metal substrate can also be a stainless steel substrate. Moreover, the surfaces of the substrate to be coated are not particularly limited and thus the substrate can be a flat substrate, a curved substrate, or a patterned substrate.

In the heat-spreading element with an AlN film and its manufacturing method of the present invention, the substrate can be coated with an AlN film by any practicable deposition methods, for example, direct current (DC) sputtering, pulsed DC sputtering, magnetron sputtering, radio frequency (RF) sputtering system, evaporation, chemical vapor deposition, plasma-enhanced chemical vapor deposition, inductively-coupled plasma deposition, microwave electron cyclotron resonance (ECR) deposition, or atomic layer deposition (ALD). Preferably, the AlN film is formed by DC sputtering, pulsed DC sputtering, RF sputtering, ECR deposition, chemical vapor deposition, and ALD.

Besides, in the heat-spreading element with an AlN film and its manufacturing method of the present invention, a heat sink can be assembled onto the substrate before or after the deposition of the AlN film. In other words, in the method of the present invention, in the step (A), a heat sink is fabricated onto the lower surface of the substrate. Alternatively, a step (C) of attaching a heat sink on the lower surface of the substrate is included posterior to the step (B). Accordingly, the heat-spreading element can further include a heat sink deposited on the lower surface of the substrate.

Moreover, in the heat-spreading element with an AlN film and its manufacturing method of the present invention, the AlN film can have a thickness from 1 nm to 10 μm. Preferably, the AlN film can have a thickness from 10 nm to 1 μm. More preferably, AlN film can have a thickness from 10 nm to 500 nm.

Other objects, advantages, and novel features of the invention will become more apparent from the following detailed description when taken in conjunction with the accompanying drawings.

### BRIEF DESCRIPTION OF THE DRAWINGS

FIG. 1 shows a perspective view of a DC sputtering system used in Example 1 of the present invention;

FIG. 2 shows a perspective view of a heat-spreading element with an AlN film in Example 1 of the present invention; and

FIG. 3 shows a perspective view of a heat-spreading element with an AlN film in Example 4 of the present invention.

### DETAILED DESCRIPTION OF THE PREFERRED EMBODIMENT

Because of the specific embodiments illustrating the practice of the present invention, one skilled in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Example 1

### AlN Film Formed by DC Sputtering

In the present example, a heat-spreading element with an AlN film is formed by DC sputtering. Herein, the DC sputtering system used in the present example is described roughly.

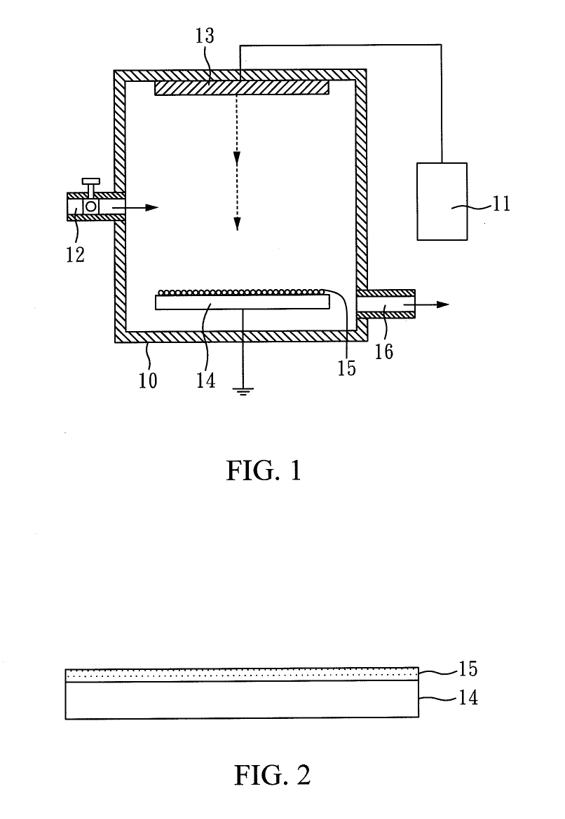

As shown in FIG. 1, it is a perspective view of a DC sputtering system used in the present example. The DC sputtering system includes: a vacuum chamber 10, a DC power supply 11, an inlet of sputtering gas 12, and a gas exhaustion outlet 16. An Al target 13 is attached onto the vacuum chamber 10 and connected to the DC power supply 11 to serve as a cathode. A substrate 14 is deposited in the other side of the vacuum chamber 10 and can be directly grounded to serve as an anode opposite to the target. In the present example, the DC power supply 11 provides a negative bias, and the substrate 14 is a Cu plate.

In the present invention, the chamber 10 is vacuumed (<10⁻⁵ Pa) via the outlet 16, and then argon (inert gas):nitrogen (reactive gas)=120 sccm:80 sccm are introduced into the chamber 10 of which vacuum is controlled at 4×10⁻³ torr. The output power of the DC power supply is set as 300 W (about 500 V) and plasma is formed within the chamber 10. When positive-charged ionized argon is attracted by the cathode and collides with the Al target 13, Al is collided out from the target (as shown in dotted line). When the collided Al is reacted with N on the heated substrate 14, an AlN film 15 is deposited and has the thickness of 100 nm.

Accordingly, the heat-spreading element with an AlN film formed in the present invention has the structure shown in FIG. 2, and it includes: the substrate 14 and the AlN film 15 deposited onto the surface of the substrate 14.

### Example 2

### AlN Film Formed by RF Sputtering

In the present example, a heat-spreading element with an AlN film is formed by RF sputtering. In the present example, the heat-spreading element with an AlN film is made in a manner substantially similar to that of Example 1, and the substrate is a Si substrate and the thickness of the AlN film is about 200 nm. The related process parameters are listed as follows: the output power of the RF power supply is 1400 W; the pressure of sputtering is controlled at 6×10⁻³ torr; the ratio of nitrogen to argon is 3:2; and the temperature of the substrate is heated to 400° C.

In addition, before AlN is deposited, the Si substrate can be selectively coated with a metal layer or an oxide layer such as Pt, Au, Cr, Mo, SiO₂ etc. to increase the adhesion between the AlN film and the substrate or to enhance the preferred orientation of the AlN film.

### Example 3

### AlN Film Formed by Chemical Vapor Deposition (CVD)

In the present example, a heat-spreading element with an AlN film is formed by CVD. In the present example, the heat-spreading element with an AlN film is the same as that of Example 2 (the same structure of the element and the same thickness of the AlN film) but made in a different manner, i.e. different method of forming the AlN film. The related process parameters are listed as follows: the temperature is set at 850° C.; the ratio of trimethyl aluminum (TMAl) to ammonium is 1:20; and the pressure of the chamber is controlled at 4 torr. The AlN film is formed on the Si substrate by chemical reaction between TMAl and ammonium.

### Example 4

### Heat-Spreading Element with a Heat Sink

In the present example, the heat-spreading element with an AlN film is made in the same manner as that of Example 1 except the manner further includes attaching a heat sink after the formation of the AlN film.

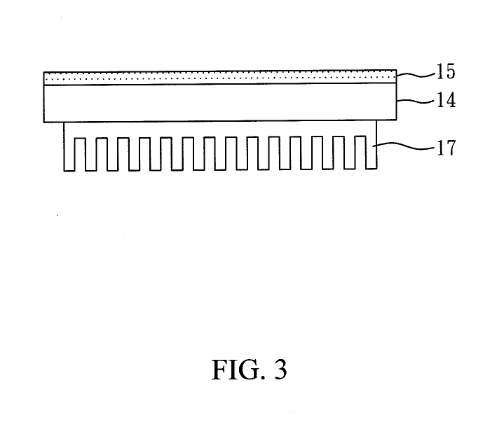

After the formation of the AlN film, a heat sink is provided and attached on the lower surface of the substrate by common methods in the art of the present invention. Accordingly, the heat-spreading element can be afforded in the present example. As shown in FIG. 3, heat-spreading element includes: the substrate 14; the AlN film 15 deposited on the upper surface of the substrate 14; and the heat sink 17 assembled onto the lower surface of the substrate. With the use of the heat sink 17, the heat generated by the electronic device can be conducted out by the AlN film 15 as well as adsorbed/dissipated by the heat sink 17 through the substrate 14.

### Example 5

### Heat-Spreading Element with a Heat Sink

In the present example, the heat-spreading element with an AlN film is made in the same manner as that of Example 1 except for the use of the heat sink on the lower surface of the substrate. Accordingly, the same structure of the heat-spreading element as that of Example 4 can be given.

In conclusion, the present invention provides a heat-spreading element with an AlN film and a method for manufacturing the same. In the method, the AlN film is formed by DC sputtering, pulsed DC sputtering, magnetron sputtering, RF sputtering system, evaporation, chemical vapor deposition, plasma-enhanced chemical vapor deposition, inductively-coupled plasma deposition, microwave ECR deposition, or ALD. Therefore, the problem of easy occurrence of run-to-run difference in the sintered AlN bulks can be solved. Besides, because the process of forming the heat-spreading element in the present invention can be integrated in current semiconductor processes, the AlN film serving as a heat-spreading element can be applied more and more wildly.

Although the present invention has been explained in relation to its preferred embodiment, it is to be understood that many other possible modifications and variations can be made without departing from the scope of the invention as hereinafter claimed.

What is claimed is:

1. A heat-spreading element with an AlN film, comprising:
a substrate having an upper surface and a lower surface; and
an AlN film deposited on the upper surface of the substrate, wherein the AlN film has a thickness from 1 nm to 10 μm and serves as a medium for heat conduction.

2. The heat-spreading element as claimed in claim 1, further comprising a heat sink assembled onto the lower surface of the substrate.

3. The heat-spreading element as claimed in claim 1, wherein the substrate is a rigid substrate, a flexible substrate, an element substrate, a multi-layered substrate, or a composite substrate.

4. The heat-spreading element as claimed in claim 1, wherein the substrate is a Si substrate, a metal substrate, a glass substrate, a plastic substrate, a ceramic substrate, a Si substrate coated with a metal film, a C—C composite substrate, a C—C composite substrate coated with a metal film, or a substrate with multiple films.

5. The heat-spreading element as claimed in claim 4, wherein the metal film is composed of Cu, Au, Pt, W, Ti, Al, Ag, Ni, or an alloy thereof.

6. The heat-spreading element as claimed in claim 1, wherein the substrate is a semiconductor chip.

7. The heat-spreading element as claimed in claim 1, wherein the substrate is a package substrate with circuits.

8. The heat-spreading element as claimed in claim 1, wherein the substrate is a flat substrate, a curved substrate, or a patterned substrate.

9. The heat-spreading element as claimed in claim 1, wherein the AlN film is deposited by direct current (DC) sputtering, pulsed DC sputtering, magnetron sputtering, radio frequency (RF) sputtering system, evaporation, chemical vapor deposition, plasma-enhanced chemical vapor deposition, inductively-coupled plasma deposition, microwave electron cyclotron resonance (ECR) deposition, or atomic layer deposition.

10. A method for manufacturing a heat-spreading element with an AlN film, comprising the following steps:
(A) providing a substrate having an upper surface and a lower surface; and
(B) forming an AlN film deposited on the upper surface of the substrate, wherein the AlN film has a thickness from 1 nm to 10 μm and serves as a medium for heat conduction.

11. The method as claimed in claim 10, wherein in the step (A), a heat sink is assembled onto the lower surface of the substrate.

12. The method as claimed in claim 10, further comprising a step (C) posterior to the step (B): attaching a heat sink on the lower surface of the substrate.

13. The method as claimed in claim 10, wherein in the step (B), the AlN film is deposited by DC sputtering, pulsed DC sputtering, magnetron sputtering, RF sputtering system, evaporation, chemical vapor deposition, plasma-enhanced chemical vapor deposition, inductively-coupled plasma deposition, microwave ECR deposition, or atomic layer deposition.

14. The method as claimed in claim 10, wherein the substrate is a rigid substrate, a flexible substrate, an element substrate, a multi-layered substrate, or a composite substrate.

15. The method as claimed in claim 10, wherein the substrate is a Si substrate, a metal substrate, a glass substrate, a plastic substrate, a ceramic substrate, a Si substrate coated with a metal film, a C—C composite substrate, a C—C composite substrate coated with a metal film, or a substrate with multiple films.

16. The method as claimed in claim 15, wherein the metal film is composed of Cu, Au, Pt, W, Ti, Al, Ag, Ni, or an alloy thereof.

17. The method as claimed in claim 10, wherein the substrate is a semiconductor chip.

18. The method as claimed in claim 10, wherein the substrate is a package substrate with circuits.

19. The method as claimed in claim 10, wherein the substrate is a flat substrate, a curved substrate or a patterned substrate.
